(19) United States
(12) Patent Application Publication
(10) Pub. No.: US 2013/0010250 A1
(43) Pub. Date: Jan. 10, 2013

(54) LIQUID CRYSTAL DISPLAY DEVICE AND MANUFACTURING METHOD THEREOF

(75) Inventor: Takatoshi Kira, Osaka (JP)

(73) Assignee: SHARP KABUSHIKI KAISHA, Osaka (JP)

(21) Appl. No.: 13/637,313

(22) PCT Filed: Feb. 9, 2011
(86) PCT No.: PCT/JP2011/052690

§ 371 Date: Sep. 25, 2012

(30) Foreign Application Priority Data
Mar. 26, 2010 (JP) 2010-071210

(51) Int. Cl. G02F 1/1339; H01L 33/08

(52) U.S. Cl. 349/153; 438/27; 257/E33.053

(57) ABSTRACT

Disclosed is a liquid crystal display device that has a narrower frame and that prevents a sealing member from entering a display region. The disclosed liquid crystal display device is provided with a first substrate and a second substrate arranged facing each another, a liquid crystal layer provided between the first and the second substrates, and a sealing member that bonds together the first and second substrates and that seals the liquid crystal layer therebetween. On the first substrate or the second substrate, a recess is made between the sealing member and the display region in the corner portion of the substrate.

### TECHNICAL FIELD

The present invention relates to a liquid crystal display device and a method of manufacturing same, and more particularly, to a reduction of the width of a bezel of a display panel.

### BACKGROUND ART

In a recent liquid crystal display device for a mobile device such as a mobile phone, a demand has been increased more than ever to reduce the width of a bezel region that is disposed around the display region and that is provided with a sealing member for sealing a liquid crystal layer, and the like, in order to make a display region that displays an image thereon larger. In other words, a demand for a slimmer bezel has been increasing. If a bezel of a display panel is made slimmer, space between a sealing member and a display region is narrowed, and in a corner portion of the bezel, in particular, because the sealing member is formed in a circular arc shape, it is possible that the sealing member enters the display region when panels are bonded and the sealing member is thereby pressed. Therefore, a structure for preventing this problem has been proposed.

Patent Document 1 discloses a first substrate 40 that is provided with a protrusion 41 on a side region on one surface thereof so as to create a difference in level, thereby making a top surface in a corner region of the first substrate 40 lower, and a sealing member 42 is applied on the side and corner regions along the periphery of the first substrate 40 as shown in FIG. 7. When a second substrate is stacked on the first substrate 40, the sealing member 42 applied thereon is pressed. However, because of the difference in level, it is possible to minimize the spread of an inner edge 44 of the sealing member in the corner region of a liquid crystal cell.

Patent Document 2 discloses that, as shown in FIG. 8, by placing an end of a display region 51 so as to face a sealing pattern 52 through a wall pattern 53 near a corner portion of an inner periphery side wall of the sealing pattern, a sealing member provided near the corner portion of the sealing pattern 52 is prevented from entering the display region 51.

### RELATED ART DOCUMENTS

### Patent Documents

Patent Document 1: Japanese Patent Application Laid-Open Publication No. 2000-193989
Patent Document 2: Japanese Patent Application Laid-Open Publication No. 2009-25355

### SUMMARY OF THE INVENTION

### Problems to be Solved by the Invention

However, in Patent Document 1, because the sealing member 42 is formed lower in the corner region, when the second substrate is stacked on the first substrate 40, the liquid crystal leaks to the outside from a region where the sealing member 42 is formed lower, which is problematic. In Patent Document 2, because the wall pattern 53 limits the spread of the sealing pattern 52, the sealing pattern 52 is formed thick near the wall pattern 53, thereby causing an uneven cell thickness, which is problematic.

The present invention was made in view of such problems, and aims at eliminating a liquid crystal leak or an uneven cell thickness, preventing a sealing member from entering a display region, and reducing a bezel width of a liquid crystal display device.

### Means for Solving the Problems

A liquid crystal display device according to the present invention includes: a first substrate and a second substrate disposed to face each other; a liquid crystal layer disposed between the first substrate and the second substrate; and a sealing member that bonds the first substrate and the second substrate to each other and that seals the liquid crystal layer therebetween, wherein, on the first substrate or the second substrate, a recess is made between the sealing member and a display region in a corner portion of the substrate.

A method of manufacturing a liquid crystal display device according to the present invention is a method of manufacturing a liquid crystal display device that includes: a first substrate and a second substrate disposed to face each other; a liquid crystal layer disposed between the first substrate and the second substrate; and a sealing member that bonds the first substrate and the second substrate to each other and seals the liquid crystal layer therebetween, the method including: forming a recess between a display region and the a location at which the sealing member is formed in a corner portion of the first substrate or the second substrate; forming the sealing member on an outside of the recess; providing a liquid crystal material on the first substrate or the second substrate; and stacking the first substrate and the second substrate, and bonding the first substrate and the second substrate such that a part of the sealing member flows into the recess.

### EFFECTS OF THE INVENTION

According to the present invention, in the corner portion of the first substrate or the second substrate, the recess is made between the sealing member and the display region. Therefore, the sealing member is stopped from reaching the display region beyond the recess, thereby preventing the sealing member from spreading into the display region. As a result, it becomes possible to provide a liquid crystal display device with a slimmer bezel.

### BRIEF DESCRIPTION OF THE DRAWINGS

FIG. 1 is a plan view of a liquid crystal display device.

FIG. 2 is a cross-sectional view of the liquid crystal display device.

FIG. 3 is an enlarged plan view of a corner portion of a frame region.

FIG. 4 is a cross-sectional view of the liquid crystal display device before bonding substrates thereof.

FIG. 5 is an explanatory plan view showing how a sealing member spreads when a recess is not provided.

FIG. 6 is an explanatory plan view showing how the sealing member spreads when the recess is provided.

FIG. 7 is a plan view of a conventional liquid crystal display device.

FIG. 8 is a plan view of the conventional liquid crystal display device.

### DETAILED DESCRIPTION OF EMBODIMENTS

An embodiment of the present invention will be described below in detail with reference to the figures. The present invention is not limited to the embodiment described below.

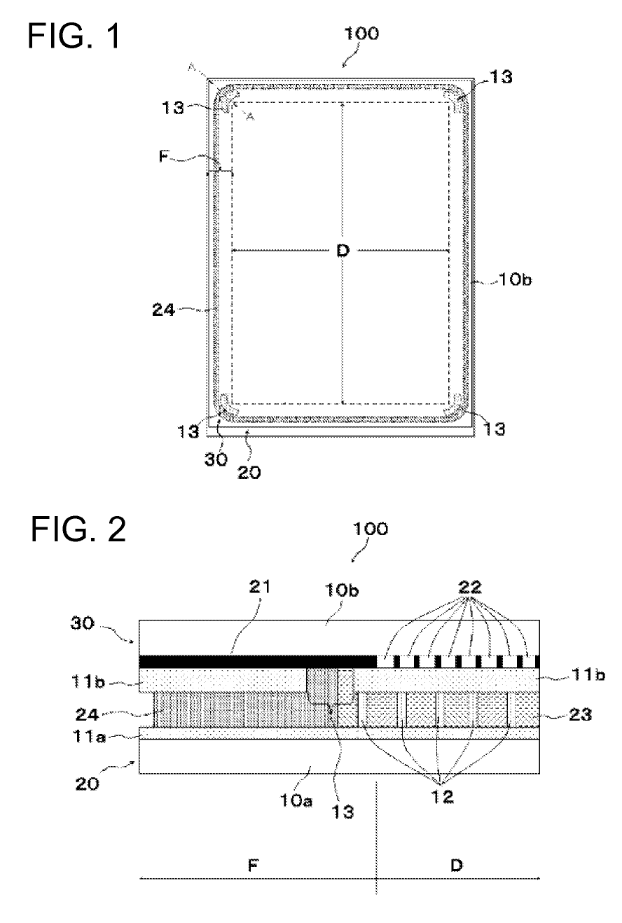

FIG. 1 is a plan view showing a liquid crystal display device 100 of the present invention. The liquid crystal display device 100 is provided with a TFT substrate 20 used as a first substrate, a CF substrate (color filter substrate) 30 that is disposed to face the TFT substrate 20 and used as a second substrate, a liquid crystal layer (not shown) provided between the TFT substrate 20 and the CF substrate 30, and a sealing member 24 formed in a frame shape to bond the TFT substrate 20 and the CF substrate 30 to each other and to seal the liquid crystal layer therebetween. On the liquid crystal display device 100, a rectangular-shaped display region D for displaying an image and a frame-shaped bezel region F around the display region D, which has the sealing member 24 disposed thereon, are defined, respectively.

FIG. 2 is a cross-sectional view of a corner portion of the liquid crystal display device 100 along the one-dot chain line A-A in FIG. 1.

The TFT substrate 20 is provided with an insulating substrate 10a, a plurality of gate lines (not shown) disposed on the insulating substrate 10a so as to extend in parallel with each other, a plurality of source lines (not shown) disposed so as to extend in parallel with each other in a direction orthogonal to the respective gate lines, a plurality of TFTs (not shown) disposed at respective intersections where the respective gate lines and the respective source lines orthogonally cross, an organic film 11a disposed so as to cover the respective TFTs, and a plurality of pixel electrodes (not shown) disposed on the organic film 11a in a matrix. On the organic film 11a, columnar spacers 12 that define the thickness of a liquid crystal layer 23 are disposed. The thickness of the organic film 11a is 2 to 4 μm, for example. The height of the columnar spacer 12 is 5 μm, for example.

The CF substrate 30 is provided with an insulating substrate 10b, a black matrix 21, and a color filter layer 22. The black matrix 21 is disposed in a frame shape in the bezel region F on the insulating substrate 10b, and is disposed in a grid pattern in the display region D, which is inside the frame. The color filter layer 22 includes red layers, green layers, and blue layers, which are respectively disposed in corresponding grids of the black matrix 21. On the black matrix 21 and the color filter layer 22, a common electrode (not shown) and an organic film 11b that serves as an overcoat layer are disposed.

As shown in FIGS. 1 and 2, in a corner portion of the bezel region F of the CF substrate 30, a recess 13 is formed between the display region D and an area where the sealing member 24 is to be formed by removing the organic film 11b through dry etching. The depth of the recess 13 is the same as the thickness of the organic film 11b, which is 2 to 4 μm, for example.

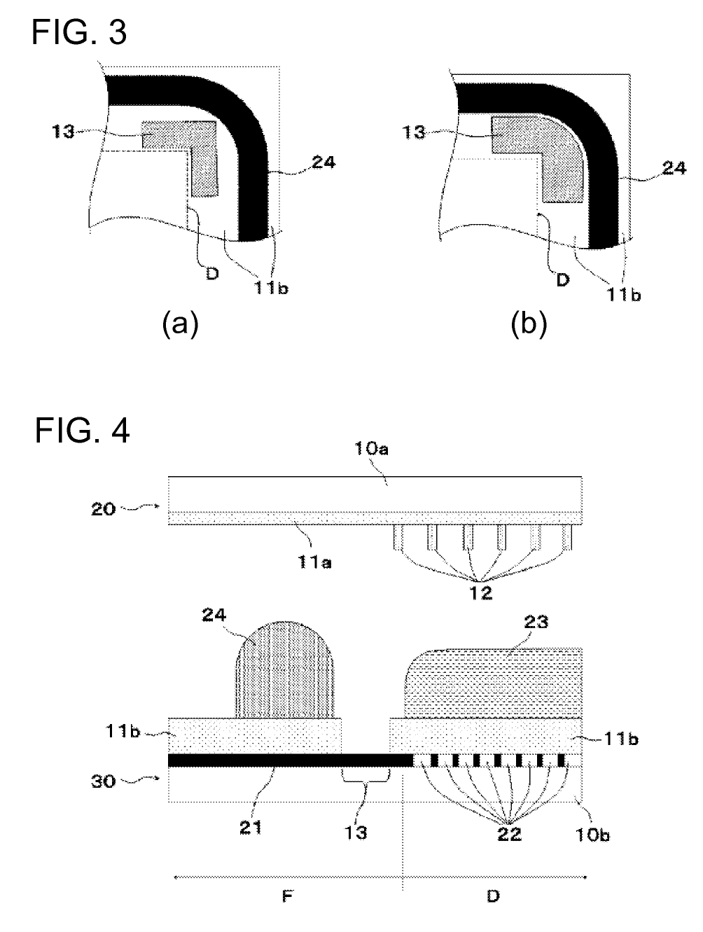

FIG. 3 shows enlarged schematic plan views of a portion around the recess 13. As shown in FIG. 3(a), the recess 13 is formed such that at least the inner side thereof is rectangular so as to be placed near the display region D. As shown in FIG. 3(b), it is preferable that the recess 13 be made as large as possible by forming an outer side thereof in a circular arc shape that coincides with the curvature of an inner side of the sealing member 24 and by placing the recess 13 closer to both the display region D and the sealing member 24. When the recess 13 is made large, even if the formed sealing member 24 becomes thick, it is possible to prevent the sealing member 24 from reaching the display region D beyond the recess 13 when the sealing member 24 is pressed.

FIG. 4 is a cross-sectional view of a corner portion of the liquid crystal display device 100 along the one-dot chain line A-A in FIG. 1, showing a state before the TFT substrate 20 and the CF substrate 30 are bonded.

On the organic film 11b in the bezel region F of the CF substrate 30, the sealing member 24 made of a thermosetting resin or a UV-curable resin such as an epoxy-based adhesive, for example, is formed using a dispenser device. In the corner portion of the frame region F, the sealing member 24 is placed outside of the recess 13 so as not to overlap the recess 13. By placing the sealing member 24 so as not to overlap the recess 13, the height of the sealing member 24 that was formed can be even on the entire bezel region F, thereby preventing the liquid crystal layer 23 from leaking to the outside of the sealing member 24 when bonding the substrates.

In the CF substrate 30 having the sealing member 24 formed thereon, the nematic liquid crystal material 23 having electrooptic characteristics is provided on the display region D by the dripping method or the like. After the liquid crystal material 23 is provided, the CF substrate 30 is stacked on the TFT substrate 20 having the columnar spacers 12 formed therein. As a result, as shown in FIG. 1, the liquid crystal display device 100 having the liquid crystal layer 23 sealed between the TFT substrate 20 and the CF substrate 30 by the sealing member 24 is formed.

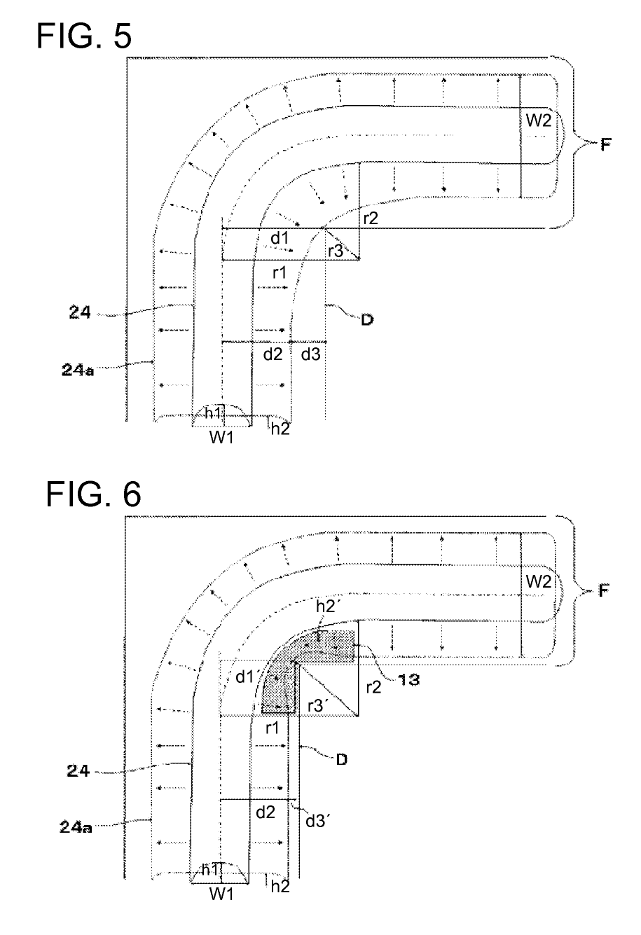

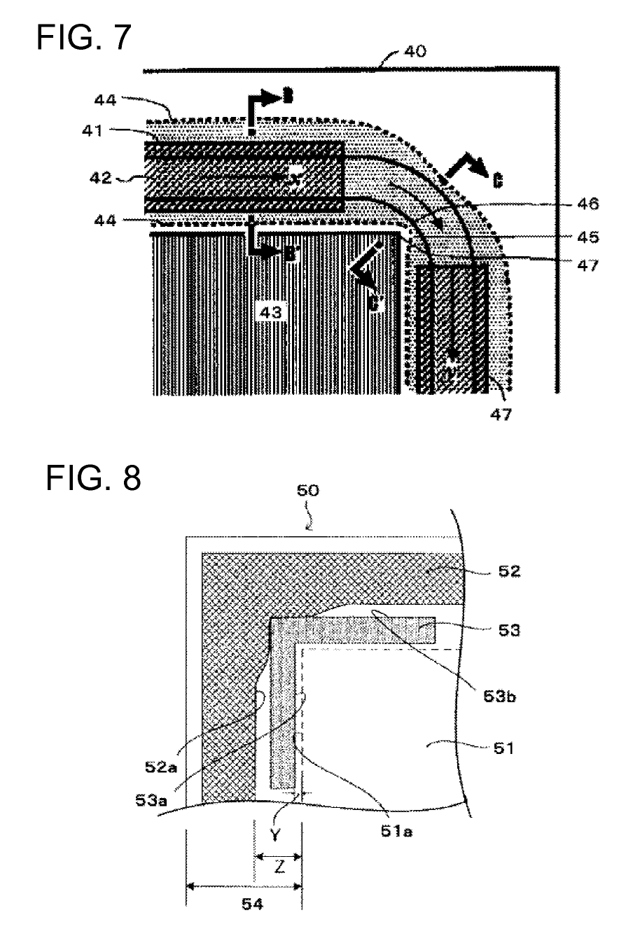

FIG. 5 is a schematic plan view showing how the sealing member 24 is pressed and thereby spreads outwardly when the TFT substrate 20 and the CF substrate 30 are stacked. The sealing member 24 is pressed between the TFT substrate 20 and the CF substrate 30, and the width (W2) of a sealing member 24a after bonding thereby becomes wider than the width (W1) of the sealing member 24 at the time when the sealing member 24 was formed. The sealing member 24 in a side portion spreads differently compared to the sealing member 24 in a corner portion. The sealing member 24 in the side portion is pressed and spreads out evenly to both sides from the width W1, which is the width at the time of forming the sealing member 24. The sealing member 24 in the corner portion, however, spreads in a direction to the center of the curvature in a more concentrated manner when pressed. Consequently, a spread width to the inside is increased, and therefore, the sealing member 24 in the corner portion tends to be closer to the display region D compared to the sealing member 24 in the side portion. Because of this, a location of the sealing member 24 formation needs to be determined by taking into account a shape of the sealing member 24a after bonding in the corner portion so as to ensure that the sealing member after bonding 24a does not enter the display region D.

The respective shapes of the sealing member 24 in the corner portion before and after the substrates are bonded can be expressed by Formula 1.

(Formula 1)

¼π(r1²−r2²)×h1×(⅔)=¼π(r1²−r3²)×h2 Formula 1

Here, “r1” represents a curvature radius when the sealing member 24 is formed in the corner portion. When the center of r1 is set to a reference point, “r2” represents a location of an inner side of the sealing member immediately after the sealing member 24 is formed, and “r3” represents a location of the inner side of the sealing member after the substrates are bonded. Further, “h1” represents a height of the sealing member 24 immediately after the sealing member 24 is formed, and “h2” represents the height of the sealing member after bonding 24a.

The location “r3” of the inner side of the sealing member in the corner portion after the substrates are bonded can be derived from (Formula 2) that is transposed from Formula 1.

(Formula 2)

r3={square root over ((1/h2)×(h2×r1²−(r1²−r2²)×h1×(⅔))))} Formula 2

In the conventional liquid crystal display device, when r1=500 μm, r2=400 μm, h1=20 μm, and h2=5 μm, for example, the location “r3” of the inner side of the sealing member after the substrates are bonded is 100 μm, according to Formula 2.

When the location of the sealing member 24 is determined such that the location “r3” of the inner side of the sealing member derived as above comes to the closest point to the display region D before making contact therewith, a location “d1” of the sealing member 24 formed in the side portion can be derived from Formula 3.

(Formula 3)

d1=r1−(r3/\sqrt{2}) Formula 3

In the conventional liquid crystal display device, when r1=500 μm and r3=100 μm, for example, “d1” is derived to be 430 μm. That is, when the location at which the sealing member 24 is to be formed is determined so as to ensure that the location “r3” of the inner side of the sealing member in the corner portion after the substrates are bonded is not in contact with the display region D, the location of the sealing member 24 formation in the side portion needs to be at least 430 μm away from the display region D.

On the other hand, a spread width “d2” of the sealing member after bonding 24a in the side portion can be derived from Formula 4.

(Formula 4)

d2=(W1×h1×(⅔))/h2/2 Formula 4

In the conventional liquid crystal display device, when the sealing member width (W1) immediately after the sealing member is 200 μm, for example, the spread width “d2” of the sealing member 24a is derived to be 260 μm. Therefore, when the location for forming the sealing member 24 (d1=430 μm) is determined with reference to the location “r3” of the inner side of the sealing member in the corner portion, the location of the inner side of the sealing member after bonding 24a in the side portion is away from the display region D as much as d3=170 μm (d3=d1−d2), and the bezel region F is at least 170 μm larger than the sealing member width.

FIG. 6 is a schematic plan view showing how the sealing member 24 is pressed and spreads out when the TFT substrate 20 and the CF substrate 30 are stacked in the liquid crystal display device 100 of the present invention. In the liquid crystal display device 100 of the present invention, the recess 13 is formed inside of the location for forming the sealing member 24 in the corner portion, such that the pressed sealing member 24a flows into the recess 13 in the corner portion. The height (h2) of the sealing member 24a after bonding is set to 5 μm except at the recess 13. The height (h2′) at the recess 13 is 8 μm when the depth of the recess 13 is 3 μm, for example.

Therefore, compared with the conventional liquid crystal display device, the height of the sealing member 24a (h2′) is increased to 8 μm, and because of this, the location “r3′” of the inner side of the sealing member after bonding becomes 320 μm according to Formula 2. When the location for forming the sealing member 24 is determined with reference to the location “r3′” of the inner side of the sealing member, a location “d1′” of forming the sealing member 24 in the side portion is 270 μm according to Formula 3.

Therefore, in the liquid crystal display device of the present invention, when the location for forming the sealing member 24 (d1′=270 μm) is determined such that the sealing member 24 is not in contact with the display region D in the corner portion, it is possible to shorten the distance between the sealing member 24a and the display region D in the side portion to d3′=10 μm (d3′=d1′−d2). Therefore, it is possible to make the bezel region F smaller than that of the conventional liquid crystal display device.

According to the liquid crystal display device 100 of the present invention, the recess 13 is made between the sealing member 24 and the display region D in the corner portion of the bezel region F. Therefore, the sealing member after bonding 24a is prevented from spreading to the inside and entering the display region D. Further, because the recess 13 is not made at the location at which the sealing member 24 is to be formed, the height of the sealing member 24 that was formed can be made uniform, thereby preventing the liquid crystal layer 23 from leaking to the outside. Furthermore, because the sealing member after bonding 24a stays inside of the recess 13, and the cell at the corner portion does not become thick, the display quality can be improved.

The present invention is not limited to the embodiment described above. It is also possible to make the recess 13 in the TFT substrate 20, for example.

1. A liquid crystal display device, comprising:
a first substrate and a second substrate disposed to face each other;
a liquid crystal layer disposed between the first substrate and the second substrate; and
a sealing member that bonds the first substrate and the second substrate to each other, the sealing member sealing the liquid crystal layer therebetween,
wherein, in the first substrate or the second substrate, a recess is made between a part of the sealing member and a display region in a corner portion of the substrate.

2. The liquid crystal display device according to claim 1, wherein the recess is formed in an organic film on the first substrate or the second substrate.

3. The liquid crystal display device according to claim 1, wherein a corner portion in the display region has a rectangular shape,
wherein a corner portion of the sealing member has a circular arc shape, and
wherein an inner edge of the recess has a rectangular shape along the shape of the corner portion of the display region, and an outer edge of the recess has a circular arc shape along the shape of the corner portion of the sealing member.

4. The liquid crystal display device according to claim 1, wherein a volume of the recess is slightly larger than an amount of the sealing member that flows into the recess after spreading as a result of bonding the first substrate and the second substrate to each other.

5. A method of manufacturing a liquid crystal display device that comprises:
a first substrate and a second substrate disposed to face each other;
a liquid crystal layer disposed between the first substrate and the second substrate; and
a sealing member that bonds the first substrate and the second substrate to each other, the sealing member sealing the liquid crystal layer therebetween, the method comprising:
forming a recess between a display region and a location at which the sealing member is to be formed in a corner portion of the first substrate or the second substrate;
forming the sealing member on an outside of the recess;
providing a liquid crystal material on the first substrate or the second substrate; and
stacking the first substrate and the second substrate, and bonding the first substrate and the second substrate such that a part of the sealing member flows into the recess.

6. The method of manufacturing a liquid crystal display device according to claim 5, wherein the step of forming the recess includes forming the recess by etching an organic film on the first substrate or the second substrate.

7. The method of manufacturing a liquid crystal display device according to claim 5, wherein an inner edge of the recess formed in the step of forming the recess has a rectangular shape along a shape of the corner portion of the display region, and an outer edge of the recess has a circular arc shape along a shape of a corner portion of the sealing member.

8. The method of manufacturing the liquid crystal display device according to claim 5, wherein a volume of the recess formed in the step of forming the recess is slightly larger than an amount of the sealing member that flows into the recess after spreading as a result of bonding the first substrate and the second substrate to each other.
